(19) United States
(12) Patent Application Publication
(10) Pub. No.: US 2024/0334592 A1
(43) Pub. Date: Oct. 3, 2024

(54) BGA Element Self-Alignment Structure and Alignment Method

(71) Applicant: SHENZHEN SIPTORY TECHNOLOGY CO., LTD, Shenzhen (CN)

(72) Inventor: Dongdong Shao, Shenzhen (CN)

(21) Appl. No.: 18/735,237

(22) Filed: Jun. 6, 2024

Related U.S. Application Data
(63) Continuation of application No. PCT/CN2022/142105, filed on Dec. 26, 2022.

(30) Foreign Application Priority Data
Dec. 27, 2021 (CN) 202111608034.5

(51) Int. Cl. H05K 1/02; H05K 1/11; H05K 3/30

(52) U.S. Cl. CPC H05K 1/0266; H05K 1/11; H05K 3/303; H05K 2201/10742; H05K 2203/166

(57) ABSTRACT

The present invention provides a BGA element self-alignment structure and an alignment method, including a printed circuit board with a first alignment structure matching with the BGA ball, and a second alignment structure on two sides of the substrate and above the printed circuit board. The BGA element is precisely aligned on the printed circuit board, which improves the mounting processing efficiency, guarantees the mounting yield of the BGA element on the printed circuit board, reduces the rework and scraping costs caused by poor BGA mounting.

### CROSS REFERENCE TO RELATED APPLICATIONS

The present application is a Continuation Application of PCT Application No. PCT/CN2022/142105 filed on Dec. 26, 2022, which claims the benefit of Chinese Patent Application No. 202111608034.5 filed on Dec. 27, 2021. All the above are hereby incorporated by reference in their entirety.

### TECHNICAL FIELD

The invention relates to the technical field of printed circuit board design and processing, particularly to a BGA element self-alignment structure and an alignment method suitable for mounting of BGA elements and printed circuit boards.

### BACKGROUND ART

Functional integration and miniaturization development of electronic products have led to an increasing packaging density and precision requirement for printed circuit boards. BGA element packaging, due to its characteristics such as small size and high reliability, is widely used in the design and production of printed circuit board products.

BGA (Ball Grid Array) refers to a technology where an array of balls is created on the bottom of the package substrate to serve as a circuit I/O terminal for interconnection with the printed circuit board (PCB). Devices packaged using this technology are a type of surface-mount devices. As shown in FIG. 1, BGA elements consist of a substrate and a BGA ball, where the substrate is the package substrate, and the BGA ball is the solder ball.

### Technical Problems

Due to the great number of pins and complex functions of BGA elements, along with the increasing difficulty in precisely aligning and mounting BGA elements to the printed circuit board, problems such as rework and scraping caused by defects in the mounting of BGA elements have serious impacts on the yield and production efficiency of products assembled by printed circuit boards and BGA elements.

### Technical Solutions

The examples of the present invention provide a BGA element self-alignment structure and an alignment method to solve the technical problems of high precision requirement of high-density BGA assembly and easy misalignment of BGA element assembly that lead to product rework and seriously affect the product yield and production efficiency.

In a first aspect, the present invention provides a BGA element self-alignment structure. The BGA element includes a substrate and a BGA ball located on the bottom surface of the substrate, comprising a circuit board mechanism and a second alignment structure. The circuit board mechanism includes a printed circuit board and a first alignment structure located on the printed circuit board, which is used to match with the BGA ball; the second alignment structure includes a pair of jigs disposed opposite each other at intervals above the printed circuit board and limited to two sides of the substrate.

Preferably, the first alignment structure includes an aperture on the printed circuit board, a packing medium structure filled in the cavity of the aperture, and a recess matching with the shape of the BGA ball on the packing medium structure.

Preferably, the aperture is a through hole, and the packing medium structure is formed by filling the cavity of the aperture with ink.

Preferably, the aperture is a through hole, and the packing medium structure is formed by filling the cavity of the aperture with resin.

Preferably, the aperture is a blind hole, and the packing medium structure is formed by filling the cavity of the aperture with ink.

Preferably, the aperture is a blind hole, and the packing medium structure is formed by filling the cavity of the aperture with resin.

Preferably, a conducting layer is added on the top surface of the packing medium structure, and the conducting layer electrically conducts the lines of the printed circuit board on both sides of the recess.

Preferably, the pair of jigs has oppositely set inclined limit surfaces.

Preferably, the angle of inclination of the inclined limit surface is in the range of 2°-20°.

Preferably, the outer surface of the pair of jigs is applied with a titanium-plated film.

Preferably, the pair of jigs is respectively fixed above the printed circuit board on both sides of the substrate.

In a second aspect, the present invention provides a BGA element self-alignment method, comprising steps of:
Obtaining the electrical design requirements for the printed circuit board and the BGA element;
Providing a first alignment structure matching with the BGA ball of the BGA element on the printed circuit board according to the obtained electrical design requirements for the printed circuit board and the BGA element;
Obtaining the size information of the BGA element;
Producing the second alignment structure according to the obtained size information of the BGA element;
Aligning the BGA element on the printed circuit board by matching the BGA ball in the first alignment structure and limiting the second alignment structure to both sides of the BGA element.

Preferably, the step of “providing a first alignment structure matching with the BGA ball of the BGA element on the printed circuit board according to the obtained electrical design requirements for the printed circuit board and the BGA element” specifically comprises steps of:
Creating plural apertures on the printed circuit board according to the obtained electrical design requirements for the printed circuit board and the BGA element;
Filing media in the cavity of the aperture to form a packing medium structure;
Molding a recess that matches with the BGA ball on the top surface of the packing medium structure;
Adding a conducting layer that electrically conducts the lines of the printed circuit board on both sides of the recess on the top surface of the packing medium structure.

Preferably, the step of “producing the second alignment structure according to the obtained size information of the BGA element” specifically comprises steps of:
Obtaining the height of a pair of jigs, the inclination angle of the inclined limit surface, and the gap between the two jigs according to the obtained size information of the BGA element;
Making a pair of jigs according to the obtained height of the pair of jigs, the inclination angle of the inclined limit surface, and the gap between the two jigs;
Applying a titanium-plated film via PVD vacuum electroplating on the surface of the pair of jigs as made.

### Advantageous Effects

Advantageous effects brought about by the technical solutions of the present invention include:

The BGA element self-alignment structure provided by the present invention precisely aligns the BGA element on the printed circuit board by arranging the first alignment structure and the second alignment structure, wherein the first alignment structure matches with the BGA ball and the second alignment structure is limited to two sides of the substrate and above the printed circuit board, which effectively guarantees the mounting yield of the BGA element on the printed circuit board, reduces the rework and scraping costs caused by poor BGA mounting, and improves the BGA element mounting processing efficiency.

### DESCRIPTION OF DRAWINGS

To provide a clearer description of the technical solutions in the examples of the present invention, a brief introduction to the drawings required in the description of the examples is given below. Obviously, the drawings described below are only some examples of the present invention. For those ordinarily skilled in the art, other drawings can also be obtained based on these drawings without inventive efforts.

FIG. 1 is a side view of BGA elements;

FIG. 2 is a bottom view of BGA elements;

FIG. 3 is a diagram showing the use state of the BGA element self-alignment structure provided by the present invention;

FIG. 4 is a diagram showing another use state of the BGA element self-alignment structure provided by the present invention;

FIG. 5 is a cross-sectional view of the printed circuit board without apertures;

FIG. 6 is a cross-sectional view of the printed circuit board with through holes provided by the present invention;

FIG. 7 is a cross-sectional view of the printed circuit board with blind holes provided by the present invention;

FIG. 8 is a cross-sectional view of the printed circuit board provided by the present invention with the through holes filled with packing medium structure;

FIG. 9 is a cross-sectional view of the printed circuit board provided by the present invention with the blind holes filled with packing medium structure;

FIG. 10 is a cross-sectional view of the printed circuit board provided by the present invention with the through holes filled with packing medium structure and recess;

FIG. 11 is a cross-sectional view of the printed circuit board provided by the present invention with the blind holes filled with packing medium structure and recess;

FIG. 12 is a cross-sectional view of the printed circuit board provided by the present invention with the through holes filled with packing medium structure, recess and conducting layer;

FIG. 13 is a cross-sectional view of the printed circuit board provided by the present invention with the blind holes filled with packing medium structure, recess and conducting layer;

FIG. 14 is a schematic diagram of a pair of jigs provided by the present invention;

FIG. 15 is a schematic diagram of a pair of jigs coated with a titanium-plated layer provided by the present invention;

FIG. 16 is a schematic diagram of a pair of jigs fixed to the printed circuit board by screwing provided by the present invention;

FIG. 17 is a schematic diagram of a pair of jigs fixed to the printed circuit board by clamping provided by the present invention.

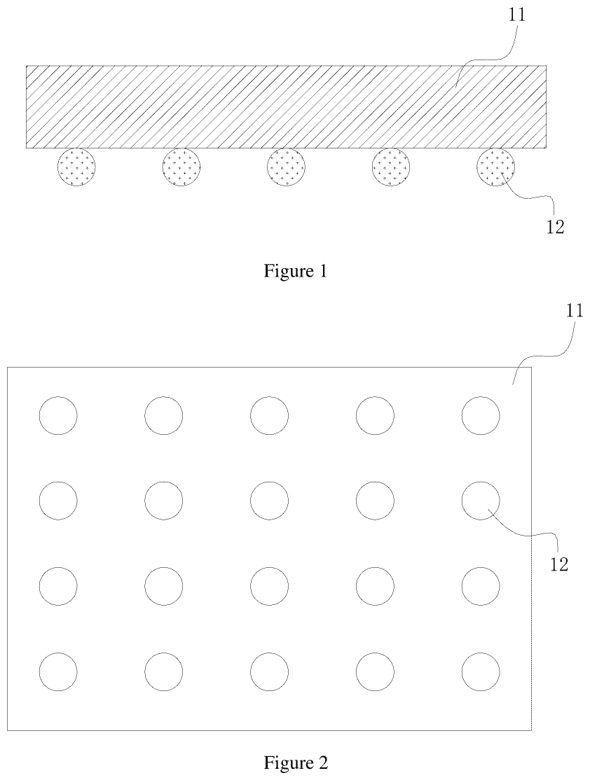

In the figures: 11—a substrate; 12—a BGA ball; 20—a printed circuit board; 21—a through hole; 22—a blind hole; 23—a packing medium structure; 24—a recess; 25—a conducting layer; 30—a jig; 301—a titanium-plated film; 31—an inclined limit surface; 32—a screw; 33—a clamping structure.

### BEST MODES FOR CARRYING OUT THE INVENTION

The examples of the present invention provide a BGA element self-alignment structure and an alignment method, which can solve the technical problems of high precision requirement of high-density BGA assembly and easy misalignment of BGA element assembly that lead to product rework and seriously affect the product yield and production efficiency.

Please refer to FIGS. 2-4. The present invention provides a BGA element self-alignment structure, comprising a circuit board mechanism and a second alignment structure. The circuit board mechanism includes a printed circuit board 20 and a first alignment structure located on the printed circuit board 20 for matching with the BGA ball 12; the second alignment structure includes a pair of jigs 30 disposed opposite each other at intervals above the printed circuit board 20 and limited to both sides of the substrate 11.

The BGA element self-alignment structure provided by the present invention precisely aligns the BGA element on the printed circuit board 20 by arranging the first alignment structure and the second alignment structure, wherein the first alignment structure matches with the BGA ball 12 and the second alignment structure is limited to two sides of the substrate 11 and above the printed circuit board 20, which effectively guarantees the mounting yield of the BGA element on the printed circuit board 20, reduces the rework and scraping costs caused by poor BGA mounting, and improves the BGA element mounting processing efficiency; different from the traditional planar mounting of BGA elements, the BGA element self-alignment structure provided by the present invention utilizes the printed circuit board 20 with recess 24, making it easier to locate and correct the positional accuracy of BGA elements.

Based on the same inventive concept, the present invention provides a BGA element self-alignment method, comprising steps of:
S110. Obtaining the electrical design requirements for the printed circuit board 20 and the BGA element;
S120. Providing a first alignment structure matching with the BGA ball 12 of the BGA element on the printed circuit board 20 according to the obtained electrical design requirements for the printed circuit board 20 and the BGA element;
S210. Obtaining the size information of the BGA element;
S220. Producing the second alignment structure according to the obtained size information of the BGA element;
S300. Aligning the BGA element on the printed circuit board 20 by matching the BGA ball 12 in the first alignment structure and limiting the second alignment structure to both sides of the substrate 11 of the BGA element.

The BGA element self-alignment method provided by the present invention achieves high-precision alignment mounting processing of BGA elements, with a low cost, flexible design, and wide range of application.

### Embodiments of the Present Invention

To make the purpose, technical solutions, and advantages of the examples of the present invention clearer, a clear and complete description of the technical solutions in the examples of the present invention is provided below by combining with the drawings in the examples of the present invention. Obviously, the described examples are only a part of the examples of the present invention, rather than all of them. Based on the examples in the present invention, the other examples obtained by those skilled in the art without inventive efforts all fall within the protection scope of the present invention.

The examples of the present invention provide a BGA element self-alignment structure and an alignment method, which can solve the technical problems of high precision requirement of high-density BGA assembly and easy misalignment of BGA element assembly that lead to product rework and seriously affect the product yield and production efficiency.

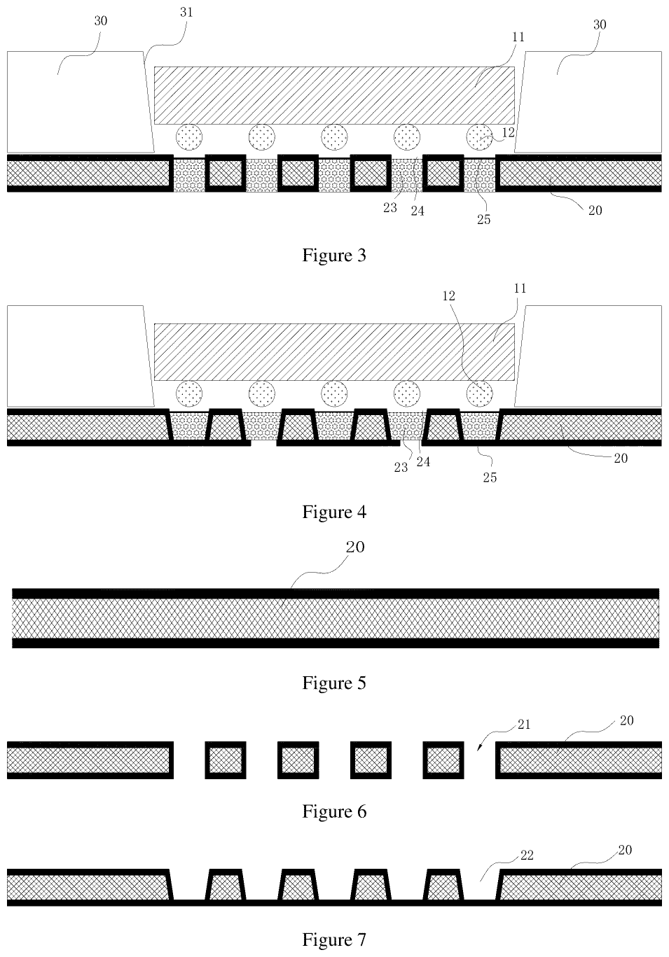

Please refer to FIGS. 3-4. The present invention provides a BGA element self-alignment structure, comprising a circuit board mechanism and a second alignment structure. The circuit board mechanism includes a printed circuit board 20 and a first alignment structure located on the printed circuit board 20 for matching with the BGA ball 12; the second alignment structure includes a pair of jigs 30 disposed opposite each other at intervals above the printed circuit board 20 and limited to both sides of the substrate 11.

The BGA element self-alignment structure provided by the present invention precisely aligns the BGA element on the printed circuit board 20 by arranging the first alignment structure and the second alignment structure, wherein the first alignment structure matches with the BGA ball 12 and the second alignment structure is limited to two sides of the substrate 11 and above the printed circuit board 20, which effectively guarantees the mounting yield of the BGA element on the printed circuit board 20, reduces the rework and scraping costs caused by poor BGA mounting, and improves the BGA element mounting processing efficiency; different from the traditional planar mounting of BGA elements, the BGA element self-alignment structure provided by the present invention utilizes the printed circuit board 20 with recess 24, making it easier to locate and correct the positional accuracy of BGA elements.

In an example, the first alignment structure includes an aperture on the printed circuit board 20, a packing medium structure 23 filled in the cavity of the aperture, and a recess 24 matching with the shape of the BGA ball 12 on the packing medium structure 23.

In an example, according to the electrical design requirements of the printed circuit board 20 and the BGA element, the aperture may be through hole 21 as shown in FIG. 6, or blind hole 22 as shown in FIG. 7, as long as it can fill the cavity of the relative position of the BGA ball 12 on the packing medium and the BGA element.

In an example, when the aperture is through hole 21, one orifice thereof is provided as the inlet for the packing medium, and the other orifice provides a flexible selective operation space for conducting layer 25 which electrically conducts the BGA ball 12 and printed circuit board 20 on two sides of the aperture.

In an example, the packing medium structure 23 is formed by filling the holes with ink or resin materials to ensure that the holes are completely filled without any gap.

In an example, conducting layer 25 is added on the top surface of the packing medium structure 23, and the conducting layer 25 electrically conducts the lines of the printed circuit board 20 on two sides of the recess 24.

In an example, the pair of jigs 30 has oppositely set inclined limit surfaces 31, which are disposed at intervals above the printed circuit board 20, with the interval, i.e. the gap, determined according to the size of the BGA element, including the height and width of the substrate 11, and the depth of the mounting of the BGA ball 12 embedded in the recess 24. A pair of inclined limit surfaces 31 is fixed at intervals above the printed circuit board 20, providing alignment guidance and final limiting effect for the alignment of the BGA element on the printed circuit board 20.

In an example, the angle of inclination of the inclined limit surface 31 is in the range of 2°-20°, determined according to the size of the BGA element and the depth of the BGA ball 12 embedded in the recess 24.

In an example, to avoid the influence of high temperature on deformation of the pair of jigs 30 during the soldering assembly process after alignment of BGA elements and the influence of the volatilization and adhesion of soldering additives or soldering aids during high-temperature soldering on the surface of the jig 30, especially the smooth walls of the inclined limit surface 31, an anti-wear and high-temperature resistant coating is applied to the outer surface of the pair of jigs 30.

In a more concrete example, a titanium-plated film 301 is electroplated to the surface of the pair of jigs 30 using vacuum PVD technology.

In an example, the thickness of the titanium-plated film 301 is controlled in the range of 3 μm-5 μm by controlling PVD vacuum electroplating parameters.

In an example, the pair of jigs 30 is detachably connected above the printed circuit board 20. After the BGA element is assembled on the printed circuit board 20, the pair of jigs 30 is removed from the circuit board.

In a concrete example, the pair of jigs 30 is respectively fixed on the printed circuit board 20 on two sides of the substrate 11 by screwing or clamping.

Based on the same inventive concept, the present invention provides a BGA element self-alignment method, comprising steps of:
S110. Obtaining the electrical design requirements for the printed circuit board 20 and the BGA element;
S120. Providing a first alignment structure matching with the BGA ball 12 of the BGA element on the printed circuit board 20 according to the obtained electrical design requirements for the printed circuit board 20 and the BGA element;
S210. Obtaining the size information of the BGA element;
S220. Producing the second alignment structure according to the obtained size information of the BGA element;
S300. Aligning the BGA element on the printed circuit board 20 by matching the BGA ball 12 in the first alignment structure and limiting the second alignment structure to both sides of the substrate 11 of the BGA element.

The BGA element self-alignment method provided by the present invention achieves high-precision alignment mounting processing of BGA elements, with a low cost, flexible design, and wide range of application.

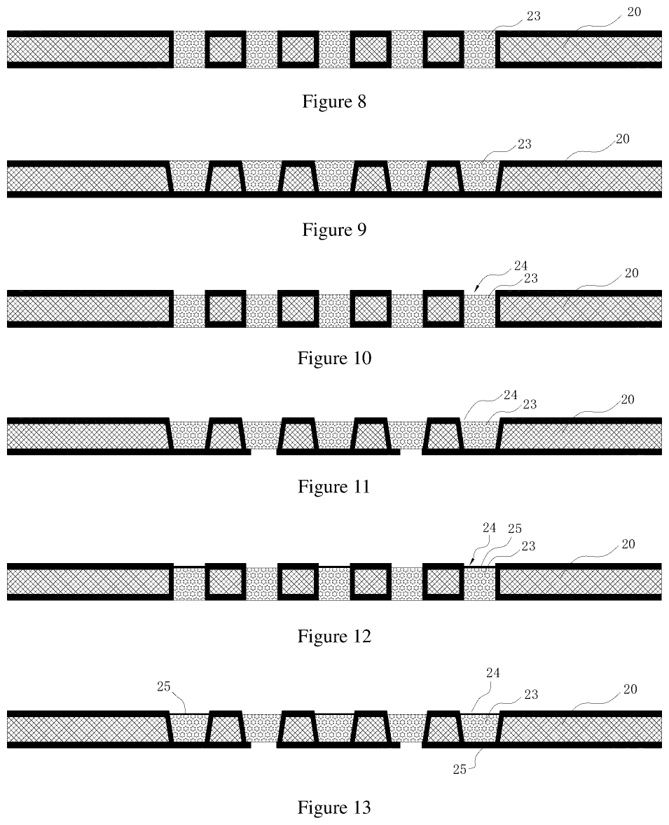

In an example, the step of “S120. Providing a first alignment structure matching with the BGA ball 12 of the BGA element on the printed circuit board 20 according to the obtained electrical design requirements for the printed circuit board 20 and the BGA element” concretely comprises steps of:
S121. Creating plural apertures that may be through holes 21 or blind holes 22 on the printed circuit board 20 according to the obtained electrical design requirements for the printed circuit board 20 and the BGA element, as shown in FIGS. 5-7;
S122. Filing media in the cavity of the aperture to form a packing medium structure 23, as shown in FIGS. 8-9;
S123. Molding a recess 24 that matches with the BGA ball on the top surface of the packing medium structure 23, as shown in FIGS. 10-11;
S124. Adding a conducting layer 25 that electrically conducts the lines of the printed circuit board 20 on both sides of the recess 24 on the top surface of the packing medium structure 23, as shown in FIGS. 12-13.

In an example, in step S121, by referring to the position of the BGA ball 12 of the BGA element and the specific size of the pin of the BGA element, apertures are formed in the corresponding area of the printed circuit board 20. The processing is simple and convenient to realize, without any need to introduce new processing technologies. The aperture processing can be achieved by using conventional circuit board processing technologies.

In an example, in step S123, the recess 24 that matches with the shape of the BGA ball 12 is molded on the top surface of the packing medium structure 23 by means of laser ablation and chemical etching.

In an example, in step S124, a conducting layer 25 is added on the top or bottom surface of the packing medium structure 23 at the aperture that needs to be conductive, according to the electrical design requirements for the printed circuit board 20 and the BGA element.

In an example, the top or bottom surface of the packing medium structure 23 is metallized, utilizing methods such as sputtering or chemical deposition to add a conducting layer 25 on the top or bottom surface of the packing medium structure 23 at the aperture that needs to be conductive.

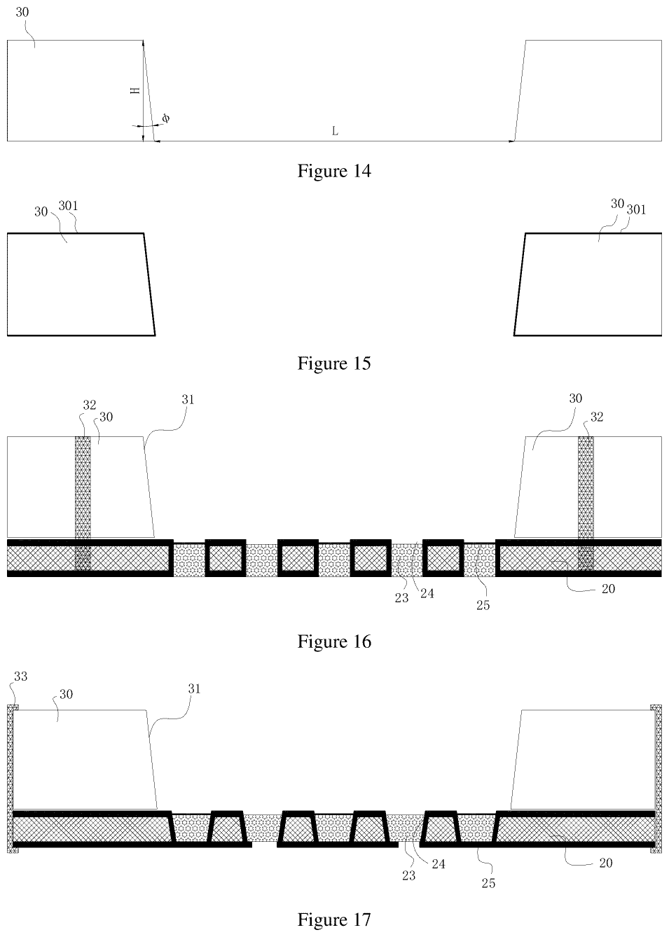

In an example, the step of “S220. Producing the second alignment structure according to the obtained size information of the BGA element” concretely comprises steps of:
S221. Obtaining the height of the pair of jigs, the inclination angle of the inclined limit surface 31, and the gap between the two jigs 30 according to the obtained size information of the BGA element;
S222. Making a pair of jigs 30 according to the obtained height of the pair of jigs 30, the inclination angle of the inclined limit surface 31, and the gap between the two jigs 30, as shown in FIG. 14;
S223. Applying a titanium-plated film 301 via PVD vacuum electroplating on the surface of the pair of jigs 30 as made, as shown in FIG. 15.

In an example, in step S222, a pair of jigs 30 that meets the size requirements is manufactured through the electroforming process, fully utilizing the high precision of the electroforming process to produce alignment assisting electroforming jigs 30, thereby further improving the alignment accuracy of BGA elements.

Wherein, as shown in FIG. 14, parameters L, H, and φ of the aperture of electroforming jigs 30 are reasonably designed to match with the size of BGA elements, where L=BGA element length+maximum positive allowance of the package size, BGA element thickness*60%≤H≤BGA element thickness*80%, H does not exceed the BGA element thickness to prevent material overlap within the aperture, and 0°≤φ≤30°.

In an example, the step of “S300. Aligning the BGA element on the printed circuit board 20 by matching the BGA ball 12 in the first alignment structure and limiting the second alignment structure to both sides of the BGA element” concretely comprises steps of:
S310. Fixing two jigs 30 onto the printed circuit board 20 at intervals according to the aperture parameter L;
S320. Lowering the BGA element through the gap between the two jigs 30 until the BGA ball 12 is embedded in the corresponding recess 24 and both sides of the substrate 11 are limited between the inclined limit surfaces 31 of the two jigs 30, thereby finishing the alignment of the BGA element with the printed circuit board 20.

In an example, the step of “S310. Fixing two jigs 30 onto the printed circuit board 20 at intervals” concretely comprises the step of:

Detachably connecting and fixing the two jigs 30 on the printed circuit board 20 at intervals.

The detachable connection can be realized by the screw fixing method as shown in FIG. 16, which performs fixing by screw 32, and can also be realized by the clamping fixing method as shown in FIG. 17, where the ends of the two jigs 30 and the two ends of the printed circuit board 20 are correspondingly clamp fixed together by clamping structure 33.

In an example, the following step is further comprised after the step of “S320. Lowering the BGA element through the gap between the two jigs 30 until the BGA ball 12 is embedded in the corresponding recess 24 and both sides of the substrate 11 are limited between the inclined limit surfaces 31 of the two jigs 30, thereby finishing the alignment of the BGA element with the printed circuit board 20”:
S400. Removing the pair of jigs 30 after the BGA element is assembled on the printed circuit board 20 by soldering to finish the assembly of the BGA element and the printed circuit board 20.

In the depiction of the present invention, it should be noted that the orientation or positional relationship to which terms such as “up” and “down” refer are based on the orientation or positional relationship shown in the figures. These terms are used merely for the convenience of describing the invention and simplifying the depiction, not to indicate or imply that the device or element referred to must have a specific orientation, or be constructed and operated in a specific orientation, and therefore cannot be understood as a limitation to the invention. Unless otherwise explicitly defined and limited, terms such as “installing” “linking” and “connecting” should be broadly understood. For example, they can refer to fixed connections or detachable connections, or integral connections; they can be mechanical connections or electrical connections; they can be direct connections or indirect connections through an intermediate medium, and can be internal connections between two elements. For those ordinarily skilled in the art, they can understand the specific meaning of the above terms in the present invention according to specific circumstances.

It needs to be noted that in the present invention, relational terms such as “first” and “second” are used solely to distinguish one entity or operation from another entity or operation and do not necessarily demand or suggest any actual relationship or order between these entities or operations. Moreover, the terms “include”, “comprise” or any of other variants are intended to encompass non-exclusive inclusion, thereby making a process, method, article, or apparatus that includes a series of elements not only include those elements but also include other elements not specifically listed, or even include elements inherent to such a process, method, article, or apparatus. Without further restrictions, the phrase “including a . . . ” does not exclude the existence of additional identical elements in the process, method, article, or apparatus that includes said element.

The above depiction is merely the embodiments of the present invention, enabling those skilled in the art to understand or implement the present invention. Various amendments to these examples will be obvious to those skilled in the field, and the general principles defined herein can be realized in other examples without departing from the spirit or scope of the present invention. Therefore, the present invention will not be limited to these examples as shown herein, but will conform to the broadest scope consistent with the principles and novel features of the present invention.

### INDUSTRIAL APPLICABILITY

The BGA element self-alignment structure provided by the present invention precisely aligns the BGA element on the printed circuit board 20 by arranging the first alignment structure and the second alignment structure, wherein the first alignment structure matches with the BGA ball 12 and the second alignment structure is limited to two sides of the substrate 11 and above the printed circuit board 20, which effectively guarantees the mounting yield of the BGA element on the printed circuit board 20, reduces the rework and scraping costs caused by poor BGA mounting, and improves the BGA element mounting processing efficiency; different from the traditional planar mounting of BGA elements, the BGA element self-alignment structure provided by the present invention utilizes the printed circuit board 20 with recess 24, makes it easier to locate and correct the positional accuracy of the BGA element, can be industrially applied and can meet the requirements for industrial applications.

What is claimed is:

1. A BGA element self-alignment structure, the BGA element including a substrate and a BGA ball on the bottom surface of the substrate, characterized in comprising:
a circuit board mechanism, including a printed circuit board and a first alignment structure located on the printed circuit board, which is used to match with the BGA ball;
a second alignment structure, including a pair of jigs disposed opposite each other at intervals above the printed circuit board and limited to two sides of the substrate.

2. The BGA element self-alignment structure according to claim 1, characterized in that the first alignment structure includes an aperture on the printed circuit board, a packing medium structure filled in the cavity of the aperture, and a recess matching with the shape of the BGA ball on the packing medium structure.

3. The BGA element self-alignment structure according to claim 2, characterized in that the aperture is a through hole, and the packing medium structure is formed by filling the cavity of the aperture with ink.

4. The BGA element self-alignment structure according to claim 2, characterized in that the aperture is a through hole, and the packing medium structure is formed by filling the cavity of the aperture with resin.

5. The BGA element self-alignment structure according to claim 2, characterized in that the aperture is a blind hole, and the packing medium structure is formed by filling the cavity of the aperture with ink.

6. The BGA element self-alignment structure according to claim 2, characterized in that the aperture is a blind hole, and the packing medium structure is formed by filling the cavity of the aperture with resin.

7. The BGA element self-alignment structure according to claim 2, characterized in that a conducting layer is added on the top surface of the packing medium structure, and the conducting layer electrically conducts the lines of the printed circuit board on both sides of the recess.

8. The BGA element self-alignment structure according to claim 2, characterized in that the pair of jigs has oppositely set inclined limit surfaces.

9. The BGA element self-alignment structure according to claim 8, characterized in that the angle of inclination of the inclined limit surface is in the range of 2°-20°.

10. The BGA element self-alignment structure according to claim 9, characterized in that the outer surface of the pair of jigs is applied with a titanium-plated film.

11. The BGA element self-alignment structure according to claim 2, characterized in that the pair of jigs is respectively fixed above the printed circuit board on both sides of the substrate.

12. A BGA element self-alignment method, characterized in comprising steps of:
obtaining electrical design requirements for a printed circuit board and the BGA element;
providing a first alignment structure matching with a BGA ball of the BGA element on the printed circuit board according to the obtained electrical design requirements for the printed circuit board and the BGA element;
obtaining size information of the BGA element;
producing a second alignment structure according to the obtained size information of the BGA element; and
aligning the BGA element on the printed circuit board by matching the BGA ball in the first alignment structure and limiting the second alignment structure to both sides of the substrate.

13. The BGA element self-alignment method according to claim 12, characterized in that:
the step of “providing a first alignment structure matching with a BGA ball of the BGA element on the printed circuit board according to the obtained electrical design requirements for the printed circuit board and the BGA element” specifically comprises steps of:
creating plural apertures on the printed circuit board according to the obtained electrical design requirements for the printed circuit board and the BGA element;
filing media in the cavity of the aperture to form a packing medium structure;
molding a recess that matches with the BGA ball on the top surface of the packing medium structure; and
adding a conducting layer that electrically conducts lines of the printed circuit board on both sides of the recess on the top surface of the packing medium structure.

14. The BGA element self-alignment method according to claim 12, characterized in that: the step of “producing a second alignment structure according to the obtained size information of the BGA element” specifically comprises steps of:
obtaining the height of a pair of jigs, the inclination angle of an inclined limit surface, and the gap between two jigs according to the obtained size information of the BGA element;
making a pair of jigs according to the obtained height of the pair of jigs, the inclination angle of the inclined limit surface, and the gap between the two jigs; and
applying a titanium-plated film via PVD vacuum electroplating on the surface of the pair of jigs as made.
